(19) United States
(12) Patent Application Publication
(10) Pub. No.: US 2005/0130338 A1
(43) Pub. Date: Jun. 16, 2005

(54) Method for producing and managing a sensor

(75) Inventors: Thomas Birkhofer, Immenstaad (DE); Aleksandar Knezevic, Friedrichshafen (DE); Ralf Mueller, Deggenhausertal (DE); Carsten Plog, Markdorf (DE)

Correspondence Address: CROWELL & MORING LLP;INTELLECTUAL PROPERTY GROUP, P.O. BOX 14300, WASHINGTON, DC, 20044-4300, US

(73) Assignee: DaimlerChrysler AG, Stuttgart (DE)

(21) Appl. No.: 10/990,968

(22) Filed: Nov. 18, 2004

(30) Foreign Application Priority Data
Nov. 19, 2003 (DE) 103 54 132.2

(51) Int. Cl. H01L 21/00

(52) U.S. Cl. 438/49

(57) ABSTRACT

A method for producing a sensor (1) for detecting at least one gas constituent in the exhaust gas of an internal-combustion engine. An electrode structure (3), acting as a capacitor, is applied to a substrate (2). A gas-permeable zeolite layer (6) is applied to the electrode structure (3) and the substrate (2). After the application of the zeolite layer (6), the sensor (1) is heated in the presence of water vapor. During the heating, a voltage is applied to the electrode structure (3). A bias voltage, superimposed on the operating voltage of the electrode structure 3, is applied to a first connection 4 and/or to a second connection 5 of the electrode structure 3.

This Application claims priority to German Application DE 103 54 132.2 filed on Nov. 19, 2003, the entire disclosure of which is expressly incorporated by reference herein.

### BACKGROUND AND SUMMARY OF THE INVENTION

The invention relates to a method of producing a sensor which can be used for the detection of at least one gas constituent in the exhaust gas of an internal-combustion engine.

From European Patent Document EP 0 426 989 A1 and German Patent Document DE 197 03 796 A1, a sensor is known for the selective detection of ammonia (NH₃) in the exhaust gas of an internal-combustion engine, whose sensitive layer consists of zeolite. A problem with known sensors is that, within a certain time after the start of the operation of the sensor—specifically, a duration of approximately 10 to 30 hours—, the zero point and the sensitivity of the latter will change. This effect, which is in the opposite direction with respect to the long-time drift of the sensor, negatively influences the achievable measuring results. Another problem is that, when such a sensor is exposed to the exhaust gases of an internal-combustion engine, the zero point will significantly drop as time passes, and the sensitivity may even be lost completely. This effect, which makes such a sensor unusable, is probably due to the temperatures peaks occurring during the driving operation of the motor vehicle in which the internal-combustion engine is installed.

However, since the construction of the sensor is definitely suitable for the measuring process to be carried out, the cause of the described problems may be found in the production method of the sensor.

It is therefore an object of the present invention to provide a method of producing and of operating a sensor which can be used for the detection of at least one gas constituent in the exhaust gas of an internal-combustion engine, so that the sensor furnishes a reliable measuring result at high exhaust gas temperatures and at any point in time of the operation.

The inventors surprisingly found that the application of a voltage to the electrode structure, particularly in the presence of water vapor, during the heating and/or in the heated condition of the sensor results in a stabilized sensor, in the case of which the problems occurring in the prior art can no longer be observed and which can therefore be used in a reliable manner for detecting the gas constituent in the exhaust gas of the internal-combustion engine, particularly when the latter is also operated by means of a rich mixture. The protective voltage applied to the electrode structure prevents the destruction of the zeolite function layer at high temperatures.

A particularly good and temperature-stable fixing of the zeolite layer is obtained when, in an advantageous further development of the invention, the sensor is heated to a temperature of more than 500° C., preferably of 600-700° C.

It was also found to be particularly advantageous for the fraction of water vapor to be 1-12% by volume and/or for a voltage in a range of from 100 mV-5V to be applied to the electrode structure.

The method according to the invention for operating the sensor is characterized in that a bias voltage superimposed on the operating voltage of the electrode structure is applied to a first connection and/or to a second connection of the electrode structure of the sensor. By the application of a bias voltage according to the invention to the connections of the electrode structure, the characteristics of the sensor are stabilized during its operation or the effects of the stressing of the sensor or an age-caused deterioration of the sensor characteristics is compensated. The bias voltage can be an offset voltage applied in addition to the operating voltage, or a voltage correcting the operating voltage.

As an embodiment of the method of operating the sensor, the bias voltage is adjusted as a function of the operating temperature of the sensor. Surprisingly, it was found that particularly a comparatively high bias voltage of approximately 4V lastingly permits the operation of the sensor also at comparatively high temperatures of more than 500° C. For this reason, it is advantageous for the bias voltage is to be defined approximately proportionally to the operating temperature.

In particular, it was found to be advantageous for the bias voltage to be adjusted with respect to the temperature detection structure and/or the heater structure and/or the equipotential surface. In this case, a positive bias voltage with respect to the above-mentioned structures or layers is preferred.

Other objects, advantages and novel features of the present invention will become apparent from the following detailed description of the invention when considered in conjunction with the accompanying drawings.

### BRIEF DESCRIPTION OF THE DRAWINGS

In the following, an embodiment of the invention is diagrammatically illustrated by means of the drawing.

FIG. 1 is a view of a sensor produced according to the method of the invention;

FIG. 2 is a first measuring diagram using a sensor known from the prior art;

FIG. 3 is a second measuring diagram using the sensor known from the prior art;

FIG. 4 is a first measuring diagram using a sensor according to the invention; and

FIG. 5 is a second measuring diagram using the sensor according to the invention.

### DETAILED DESCRIPTION OF THE DRAWINGS

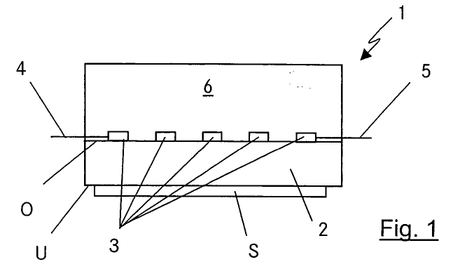

FIG. 1 illustrates a sensor 1 for detecting at least one gas constituent in the exhaust gas of an internal-combustion engine which is not shown. In particular, the sensor 1 is used for the selective detection of ammonia (NH₃) and its construction described in the following may essentially correspond to that of the sensor described in German Patent Document DE 197 03 796 A1 or European Patent Document EP 0 426 989 A1.

The sensor 1 has a substrate 2 formed, for example, of an aluminum oxide ceramic material or of another suitable material with a top side O and a bottom side U, an electrode structure 3 acting as a capacitor being applied to the top side O. The electrode structure 3 is provided with two electrical connections 4 and 5 to which, while the sensor 1 is in use, an electrical voltage, preferably an alternating voltage, is applied. A gas-permeable zeolite layer 6, which determines the sensitivity of the sensor 1 to a decisive degree and whose composition and porosity is adapted to the gas constituent to be measured, is situated on the electrode structure 3. Between the electrode structure 3 and the zeolite layer 6, another thin protective layer can be situated which, however, is not shown and which can be called a braiding.

Another layer structure formed of one or more layers can be provided below the electrode structure 3. This layer structure, which, as a whole, is marked “S”, is arranged, for example, on the bottom side U of the substrate 2 but can also be arranged completely or partially on the top side O of the substrate. The layer structure S preferably comprises one or more layers which support the sensor function. In this context, it is advantageous for this layer structure S to comprise a heater structure for heating the sensor 1 and/or a temperature detection structure and/or an equipotential surface with respective corresponding contact connections, the above-mentioned layers or structures preferably being arranged above one another and being separated from one another by insulating layers, which is not shown in detail.

The method of producing the sensor 1 is implemented as follows: The electrode structure 3 is applied to the top side O of the substrate 2, which can take place in a known manner and will therefore not be described in detail. The electrode structure 3 only partially covers the substrate. Subsequently, the zeolite layer 6 is applied to the electrode structure 3 and/or the top side O of the substrate 2, preferably by means of burning it in. After the application of the zeolite layer 6, the sensor 1 is heated in the presence of water vapor, which is not shown. During this heating, an electric voltage acting as a protective voltage is applied by way of the electric connections 4 and or 5, so that a potential difference is formed between the electrode structure 3 and the connection 4 and/or 5 and a layer of the layer structure S, which layer is used as a counterelectrode and is not shown here separately.

The temperature during the heating of the sensor 1 preferably amounts to more than 500° C., particularly preferably from 600-700° C. Furthermore, the fraction of existing water vapor during the heating amounts to from 1 to 12% by volume, and the voltage applied to the electrode structure 3 is in a range of from 100 mV to 5V with respect to the above-mentioned counterelectrode, preferably a direct voltage being applied. Depending on the composition of the zeolite layer 6 as well as the planned use of the sensor 2, the duration of the heating of the sensor 1 and the connected application of the voltage to the electrode structure 3 may amount to only 10 to 15 minutes. However, it may also be advantageous to carry out the heating for a time period of 15 hours or more and in the process apply the voltage to the electrode structure 3. In this context, it may also be provided that, already during the burning of the zeolite layer 6 into or onto the electrode structure 3 and the substrate, such a voltage is applied to the electrode structure 3. It is particularly advantageous to adjust the voltage as a function of the temperature, particularly inversely proportionally or in the opposite direction of the temperature.

As will be explained in the following, a sensor produced by means of the above-described method has considerably improved characteristics in comparison to a sensor produced according to a method of the prior art. Otherwise, this sensor can have a construction corresponding to the sensor illustrated in FIG. 1.

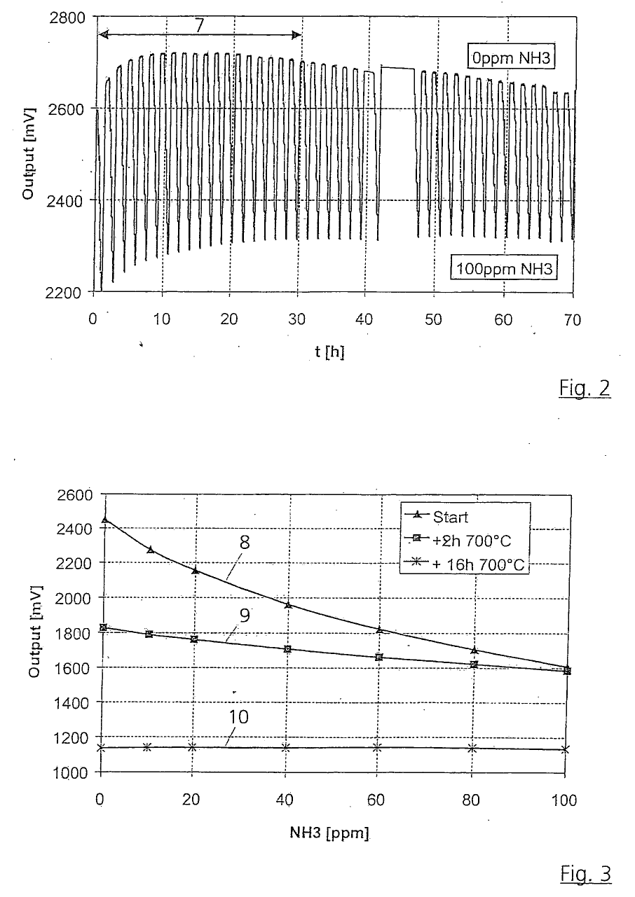

FIG. 2 shows a measuring diagram in which the NH₃ content in a gaseous analyte was measured by means of the sensor known from the prior art. Here, the output in millivolt (mV) is entered over the time (t) in hours (h). It is clearly illustrated that, within approximately 10 to 30 hours after the start of the operation of this sensor, the zero point and the sensitivity of the latter change. This effect known as the green effect is opposed to the long-time drift and is marked in FIG. 2 with the concentration stages 0, 10, 20, 40, 60, 80, 100 ppm NH₃ by means of the arrow 7. It is therefore demonstrated that a reliable measuring result cannot be achieved by means of such a sensor.

FIG. 3 shows another measuring diagram in which, by means of three characteristic curves, the course of the output of the sensor produced by means of the method known from the prior art is indicated in millivolt (mV) over the NH₃ concentration in the gaseous analyte in ppm. The line marked “8” shows the course of the output at the start of the measurement; the line marked “9” shows the course of the output after the sensor had been exposed to a temperature of 700° C. for a duration of two hours; and the line marked “10” shows the course of the output after the sensor had been subjected to a temperature stress of 700° C. for a duration of 16 hours. This demonstrates that, as the duration of the temperature stress increases, the zero point drops considerably and the sensitivity is lost completely. Such a sensor is not suitable connection with the NH₃ measurement in the exhaust gas of internal-combustion engines.

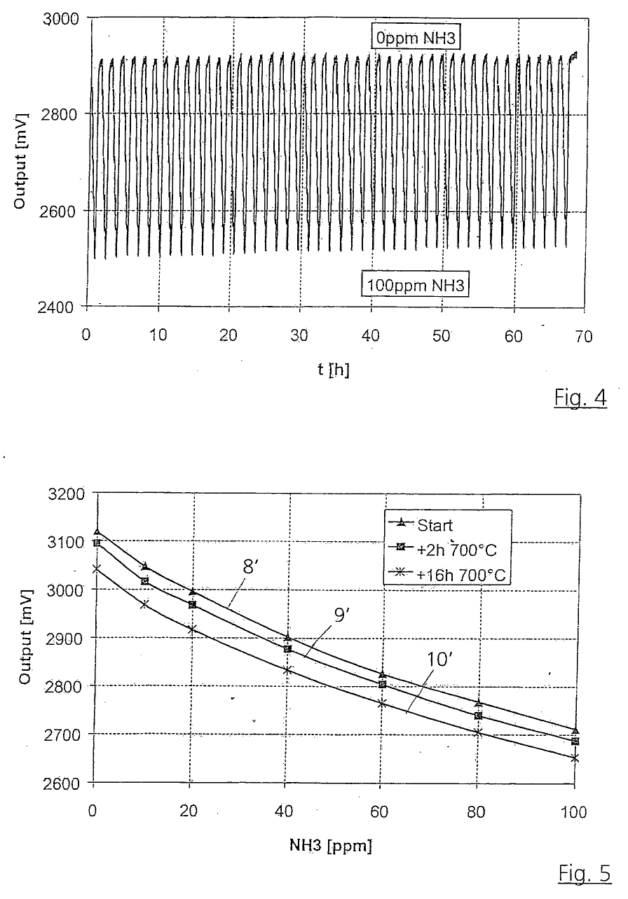

Similar to FIG. 2, FIG. 4 shows the course of the output in millivolt (mV) over the time (t) in hours (h) in the case of a sensor 1 produced by means of the above-described method. Again, concentration stages of 0, 10, 20, 40, 60, 80, 100 ppm NH₃ are provided and it is clearly demonstrated that the green effect occurring in FIG. 2 no longer takes place, but that, on the contrary, the sensor can be called stable.

Analogous to the representation in FIG. 3, FIG. 5 shows the output in millivolt (mV) of the sensor 1 produced by means of the above-described method. The line marked “8′” again shows the course of the output over the NH₃ concentration in ppm at the start of the measuring process; the line marked “9′” shows the course after the sensor 1 had been exposed for two hours to a temperature stress of 700°; and the line “10′” shows this course after a temperature stress of 700° C. for a duration of 16 hours. This diagram clearly demonstrates that the sensitivity of this sensor 1 remains stable, which is decisive for its operability. Furthermore, the zero point still changes only slightly, which can be corrected, however, by suitable measures known to a person skilled in the art.

Because the protective voltage applied to the electrode structure 3 prevents the destruction of the zeolite layer 6 at high temperatures, a stabilized sensor 1 is obtained which can be used in a reliable manner for detecting the gas constituent in the exhaust gas of the internal-combustion engine, particularly also when the latter is operated by means of a rich mixture.

The positive effects of the application of a voltage to the electrode structure 3 during the production process are particularly favorable if this voltage, optionally adapted to the requirements, is maintained also during the operation. In the following, this voltage is called bias voltage. In this case, the bias voltage preferably designed as a direct voltage is superimposed on the operating voltage, which is applied as alternating voltage for the impedance measurement to the electrode structure 3. It was found that, as a result, a reliable operation of the sensor 1 is permitted also at increased temperature of approximately 700° C. This considerably expands the applicability. A sensor 1 produced corresponding to the above explanations can, in any case, be lastingly operated above 500° C. It is advantage to adapt the bias voltage to the operating temperature; preferably, to also increase when the operating temperature rises. Even at 700° C., the sensor 1, particularly if it is produced according to the invention, can be operated reliably and for a long time if a preferably increased bias voltage of from 1V to approximately 10V is applied to the electrode structure. At operating temperatures of above approximately 500° C., a bias voltage of approximately 3V to 5V was found to be particularly advantageous.

It is advantageous for the connection 4 and/or the connection 5 of the electrode structure during the operation of the sensor to be positively adjusted with respect to an existing temperature detection structure and/or heater structure and/or equipotential surface. Particularly a grounding of an equipotential surface arranged between the electrode structure 3 and the heater structure arranged underneath as well as the adjustment of the bias voltage with respect to the equipotential surface was found to be advantageous. Likewise, it is advantageous to adjust the bias voltage with respect to the temperature detection structure.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1. A method of producing a sensor for detecting at least one gas constituent in the exhaust gas of an internal-combustion engine, comprising the steps:
applying an electrode structure to a substrate;
applying a gas-permeable zeolite layer to the electrode structure and the substrate, to form a sensor structure;
heating said sensor structure; and
applying a voltage to the electrode structure.

2. The method according to claim 1, wherein,
when the voltage is applied, the sensor structure is situated in a water-vapor-containing environment.

3. The method according to claim 1, wherein,
the sensor structure is heated to a temperature of more than 500° C.

4. The method according to claim 3, wherein said temperature is between 600° C. and 700° C.

5. The method according to claim 2, wherein,
the fraction of water vapor is from 1-12% by volume.

6. The method according to claim 1, wherein
said voltage is between 100 mV-5 V.

7. The method according to claim 1, wherein said
voltage is a direct voltage.

8. The method according to claim 1, wherein
the zeolite layer is applied by means of a burning-in to at least one of the electrode structure and the substrate.

9. The method according to claim 8, wherein,
during the burning-in of the zeolite layer, the voltage is applied to the electrode structure.

10. The method according to claim 1 further including the steps of;
providing a layer structure (S), which includes at least one of a temperature detection structure, and a heater structure, and/an equipotential surface, and
superimposing said voltage on an operating voltage of the electrode structure wherein said voltage is applied to at least on of a first connection and a second connection of the electrode structure.

11. The method according to claim 10, wherein said voltage is adjusted as a function of the operating temperature of an sensor.

12. The method according to claim 9, wherein said voltage is adjusted with respect to at least one of the temperature detection structure, and the heater structure and the equipotential surface.

13. The method according to claim 9, wherein the sensor can be lastingly operated at an operating temperature of more than 500° C. and supplies a measuring signal correlating with the ammonia content of the exhaust gas.

14. The method according to claim 2, wherein the sensor structure is heated to a temperature of more than 500° C.

15. The method according to claim 2, wherein said voltage is between 100 mV-5 V.

16. The method according to claim 3, wherein said voltage is between 100 mV-5 V.

17. The method according to claim 5, wherein said voltage is between 100 mV-5 V.

18. The method according to claim 2, wherein said voltage is a direct voltage.

19. The method according to claim 3, wherein said voltage is a direct voltage.

20. The method according to claim 4, wherein said voltage is a direct voltage.
